(19) United States
(12) Patent Application Publication
(10) Pub. No.: US 2009/0246361 A1
(43) Pub. Date: Oct. 1, 2009

(54) METHOD FOR MANUFACTURING DIELECTRIC ELEMENT

(75) Inventors: Hitoshi SAITA, Tokyo (JP); Naoto TSUKAMOTO, Tokyo (JP); Akira SHIBUE, Tokyo (JP); Kenji HORINO, Tokyo (JP)

Correspondence Address: OLIFF & BERRIDGE, PLC, P.O. BOX 320850, ALEXANDRIA, VA, 22320-4850, US

(73) Assignee: TDK CORPORATION, Tokyo (JP)

(21) Appl. No.: 12/409,886

(22) Filed: Mar. 24, 2009

(30) Foreign Application Priority Data
Mar. 31, 2008 (JP) P2008-091879
Feb. 3, 2009 (JP) P2009-022872

(51) Int. Cl. B05D 5/12

(52) U.S. Cl. 427/126.3

(57) ABSTRACT

The present invention provides a method for manufacturing a dielectric element in which a dielectric film is formed by a chemical solution deposition method, with enhanced tolerance of the dielectric film of wet processes. A method for manufacturing a dielectric element comprises a process of heating a film of a solution of a precursor on a metal layer in an oxidizing atmosphere, to form a calcined film comprising a dielectric material generated from the precursor, and a process of annealing the calcined film to form a dielectric film comprising the dielectric material that has been crystallized. The dielectric material is a metal oxide which forms a perovskite-structure crystal having A sites and B sites. The solution of the precursor comprises an element occupying A sites and an element occupying B sites in the dielectric film, at a molar ratio of the element occupying A sites to the element occupying B sites of 0.85 or higher and 1.00 or lower. The annealing temperature of the solution film is 400 to 480° C.

### BACKGROUND

1. Field of the Invention

This invention relates to an dielectric element such as a thin film capacitor, comprising a dielectric film.

2. Related Background Art

A method called the chemical solution deposition method is one method for forming a dielectric film comprising a metal oxide on a metal film. In the chemical solution deposition method, generally a solution which is a precursor of a metal oxide is applied onto the metal layer, and the applied solution is heated to generate the metal oxide from the precursor, and further heating is performed to drive crystallization of the metal oxide (see for example Japanese Patent Application Laid-open No. 2006-196848, Japanese Patent Application Laid-open No. 2006-328531, and Japanese Patent Application Laid-open No. 2007-66754). The chemical solution deposition method has advantages compared with CVD or other vacuum process methods such as the ability to reduce manufacturing costs.

The metal layer in such a dielectric element often comprises one or more elements selected from among Cu, Ni, and Al. However, in the prior art, there has been the problem that a dielectric film formed by the chemical solution deposition method on such a metal layer tends to easily be damaged in subsequent wet processes such as plating and wet etching. For example, when an electrode metal layer is formed on the dielectric film, and the electrode is patterned using wet etching or another process to fabricate a thin film capacitor, there are cases in which the insulating resistance value of the thin film capacitor is greatly reduced compared with cases in which the electrode metal layer is fabricated by sputtering using a metal mask or another method. And, if wet etching is used for patterning, there are cases in which separation of the dielectric film occurs due to action of the etchant.

### SUMMARY

Hence an object of this invention is to provide a method, when forming a dielectric element in which the dielectric film is formed by the chemical solution deposition method, of improving the tolerance of the dielectric film of wet processes.

A method for manufacturing a dielectric element of this invention comprises a process of forming a film of a solution comprising a precursor on a metal layer comprising Ni or an alloy comprising Ni; a process of heating the solution film on the metal layer in an oxidizing atmosphere, to form a calcined film comprising a dielectric material generated from the precursor; and a process of annealing the calcined film to form a dielectric film comprising the dielectric material that has been crystallized. The dielectric material is a metal oxide which forms a perovskite-structure crystal having A sites and B sites. The solution of the precursor comprises an element occupying A sites and an element occupying B sites in the dielectric film, at a molar ratio of the element occupying A sites to the element occupying B sites of 0.85 or higher and 1.00 or lower. The temperature of heating (calcining) of the solution film is 400 to 480° C.

By means of the above method of manufacture of this invention, the tolerance of the dielectric film thus formed of wet processes can be enhanced.

It is preferable that the elements occupying A sites be at least one element selected from the group consisting of Ba, Sr, Ca, and Pb, and that the elements occupying B sites be at least one element selected from the group consisting of Ti, Zr, Hf, and Sn. By employing the above-described elements occupying B sites, there is a tendency for the DC bias dependence of the capacitance to be decreased.

In the above-described processes of forming the dielectric film, it is preferable that the calcined film be annealed at 400 to 1200° C. in a reduced-pressure atmosphere at 0.001 to 10 Pa. By this means, a dielectric film having a higher dielectric constant can be formed.

By means of this invention, a method for manufacturing a dielectric element in which a dielectric film is formed using the chemical solution deposition method can be used to fabricate dielectric film with enhanced tolerance of wet processes.

### BRIEF DESCRIPTION OF THE DRAWINGS

FIG. 1 is a process diagram showing an embodiment of a dielectric element manufacturing method.

### DETAILED DESCRIPTION OF EMBODIMENTS

Below, a preferred embodiment of the invention is explained in detail. However, the invention is not limited to the following embodiment.

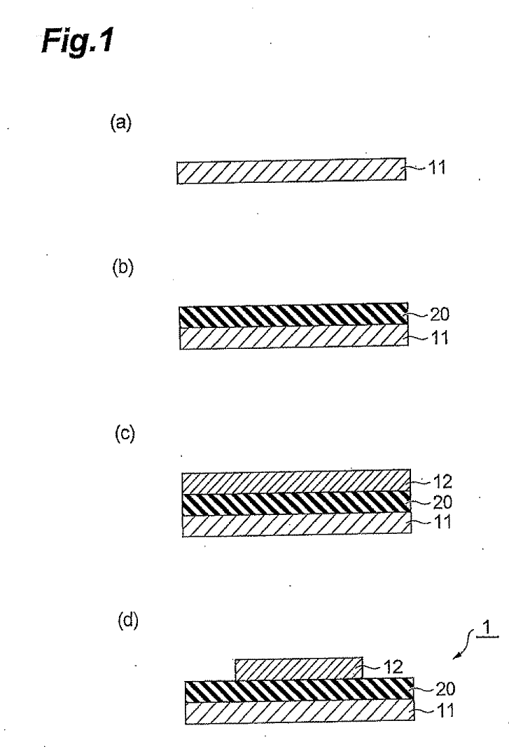

FIG. 1 is a process diagram showing, through end-face views, an embodiment of a dielectric element manufacturing method. The manufacturing method shown in FIG. 1 primarily comprises a process of preparing a first metal layer 11 ((a) of FIG. 1); a process of forming a film 20 of a solution comprising a precursor on the first metal layer 11 ((b) of FIG. 1); a process of heating the film 20 of the solution on the first metal layer 11 in an oxidizing atmosphere, and forming a calcined film 20 comprising a dielectric material generated from the precursor ((b) of FIG. 1); a process of heating the calcined film 20, and forming a dielectric film 20 comprising a crystallized dielectric material ((b) of FIG. 1); a process of forming a second electrode layer 12 on the dielectric film 20, opposing the first metal layer 11 ((c) of FIG. 1); and a process of patterning the second metal layer 12 on the dielectric film 20 ((d) of FIG. 1). At this time, the first metal layer 11 may also be patterned. The dielectric element 1 thus obtained is a thin film capacitor comprising a pair of opposing electrodes 11 and 12, and a dielectric film 20 provided therebetween.

As the first metal layer 11, it is preferable that metal foil, formed from at least one element selected from among the base metals Cu, Ni, and Al, be used; here, in particular, Ni or an alloy comprising Ni (such as NiPd) are used. No limitations in particular are placed on the method of fabrication of the metal foil, but, for example, a rolling method, electrolytic method, or powder metallurgical method may be used. It is preferable that the surface of the first metal layer 11 on the side on which the dielectric film 20 is to be formed be polished in advance. By this means, reductions in yields arising from the occurrence of short-circuits due to surface roughness are prevented. No limitations in particular are placed on the polishing method, and for example electrolytic polishing, CMP, or other methods may be adopted as appropriate.

A solution, in which a precursor which is decomposed by heating to produce a metal oxide is dissolved by a solvent, is applied onto the first metal layer 11. No limitations in particular are placed on the method of application, and for example spin coating, spray coating, die coating, slit coating, printing, or other methods can be used.

The solution is in some cases called a metal-organic decomposition (MOD) solution. As the precursor comprised by the MOD solution, it is preferred that a metal-organic salt be used. As the solvent used to dissolve the precursor, an alcohol or similar is used. As the metal-organic salt, for example an octyl acid salt is used.

The metal oxide generated from the precursor is a perovskite-structure crystal, having A sites and B sites, formed within the dielectric film 20. Stoichiometrically, a metal oxide forming crystals with such a perovskite structure has a composition expressed by the general formula ABO₃. A and B are respectively elements occupying A sites and B sites in the perovskite structure. The molar ratio (A/B) of element A to element B is stoichiometrically equal to 1.

The MOD solution is adjusted such that the elements A and B are comprised with a molar ratio of element A to element B (A/B) of 1.00 or lower. The ratio of element A to element B can be adjusted arbitrarily through the mixture ratio of the metal-organic salt used as the precursor. It is preferable that A/B be 0.85 or higher. This is because, if A/B is less than 0.85, the insulating resistance of the film itself is degraded, and crystals do not tend to readily form the perovskite structure. The molar ratio A/B in the dielectric film 20 thus formed is effectively the same as in the MOD solution used as the starting material.

It is preferable that the elements A occupying A sites comprise at least one element selected from the group consisting of Ba, Sr, Ca, and Pb. And, it is preferable that the elements B occupying B sites comprise at least one element selected from the group consisting of Ti, Zr, Hf, and Sn. In this case, the composition of the dielectric film 20 thus formed can be represented by the general formula:

A_{y}BO₃

In this formula, y satisfies 0.85≦y≦1.00 (and more preferably 0.85≦y<1.00).

The MOD solution film formed by application is heated in an oxidizing atmosphere at 400 to 480° C. If the heating temperature is less than 400° C., the advantageous result in improving the tolerance the dielectric film is reduced, and if 480° C. is exceeded the first metal layer 11 is damaged due to oxidation or other causes, and the dielectric film quality is worsened, possibly resulting in short-circuits. In order to more prominently draw out the advantageous results of this invention, it is preferable that the temperature be from 400 to 440° C. The oxidizing atmosphere typically comprises oxygen at a concentration of pO₂≧1 ppm.

Through this heating (calcination), the precursor in the MOD solution is decomposed, and the metal oxide is generated. After heating, nearly all the metal oxide in the calcined film 20 is in an amorphous state. However, the calcined film 20 may comprise crystallized metal oxide. And, small amounts of solvent and precursor may also remain in the calcined film 20.

The calcined film 20 is further heated, to drive crystallization of the dielectric material (metal oxide). Through this annealing, a dielectric film 20 comprising sufficiently crystallized dielectric material is obtained. In order to raise the dielectric constant of the dielectric film 20 obtained, it is preferable that annealing of the calcined film be performed in a reduced-pressure atmosphere at 0.001 to 10 Pa. And, it is more preferable that the heating temperature be 600 to 1000° C., and it is preferable that the heating time be approximately 10 to 120 minutes.

Calcination and annealing may be repeated a plurality of times, to form a dielectric film 20 having a desired film thickness. In this case, after layering a plurality of layers of calcined film, annealing can be performed in a single operation for crystallization.

Next, the second metal layer 12 is formed on the dielectric film 20. No limitations in particular are placed on the metal comprised by the second metal layer 12, but similarly to the first metal layer, a base metal or an alloy thereof is preferable, and Cu is particularly preferable. As the method of formation of the second metal layer, a sputtering method, a plating method, or similar can be adopted.

The second metal layer 12 thus formed is patterned by removal of a portion thereof. For example, a resist pattern is formed covering the portions of the second metal layer 12 which are to be left, and the portions of the second metal layer 12 not covered by this resist pattern are removed by etching. Etching may be performed using dry etching or wet etching, but when wet etching in particular is used, characteristics of the dielectric film 20 are easily degraded by the effects of the etchant, and so a method of this invention is particularly advantageous. As the etchant, for example an iron chloride aqueous solution or a copper chloride aqueous solution is used.

Through the above processes, a thin film capacitor 1 is obtained. The first metal layer 11 and second electrode layer 12 function as the electrodes of the thin film capacitor.

### EXAMPLES

Below, examples are used to explain the invention more specifically. However, the invention is not limited to the following examples.

### Example 1

Barium octylate, strontium octylate, and titanium octylate were dissolved in butanol, to prepare a MOD solution. When adjusting the MOD solution, the barium octylate, strontium octylate, and titanium octylate were added at molar ratios such that the composition of the dielectric film formed, when represented as (Ba₁₋ₓSrₓ)_{y}TiO₃, was such that x and y had the values indicated in Table 1 below. The sum of the concentrations of the barium octylate, strontium octylate, and titanium octylate in the MOD solution was 0.1 mole/kg.

TABLE 1

| | Ba | Sr | (Ba + Sr)/Ti | |
|---|---|---|---|---|
| No. | 1 − x | x | y(A/B) | Ti |
| #1 | 0.7 | 0.3 | 1.03 | 1 |
| #2 | 0.7 | 0.3 | 1 | 1 |
| #3 | 0.7 | 0.3 | 0.97 | 1 |
| #4 | 0.7 | 0.3 | 0.9 | 1 |
| #5 | 0.7 | 0.3 | 0.85 | 1 |
| #6 | 0.7 | 0.3 | 0.8 | 1 |

The MOD solution thus prepared was applied into Ni foil 100 mm on a side using a spin coater. The Ni foil was fabricated using an electrolytic method, and the surface thereof was flattened by the CMP method in advance.

After application, the MOD solution on the Ni foil was heated in air for 10 minutes, butanol in the MOD solution was removed, and thermal decomposition (calcination) of the metal-organic salt was induced. Processes from the application of the MOD solution to the calcination were repeated a plurality of times. The heating temperature was set to each of the temperatures shown in Table 2, in the range from 320 to 500° C.

After calcination, the calcined film was annealed by heating for 30 minutes at 900° C. in a reduced-pressure atmosphere, to drive crystallization. As a result, a dielectric film of film thickness 300 nm with advanced crystallization was obtained.

The compositions of the dielectric films obtained were conformed by fluorescent X-ray spectroscopy to effectively match the compositions of Table 1.

A Cu electrode of size 5×5 mm was formed on the dielectric film formed in this way by one of the following methods, to obtain a thin film capacitor for use in evaluations.
Sputtered Cu electrode: A Cu electrode of thickness 5 μm was formed by sputtering using a metal mask.
Plated and patterned Cu electrode: A Cu seed layer (thickness 0.2 μm) was formed by sputtering over the entirety of the dielectric film (100 mm on a side), and on this a plating method was used to form a plated Cu layer, to obtain a Cu plated electrode, the total thickness, seed layer and plated layer, of which was 5 μm. A resist pattern was formed on this Cu plated electrode, and portions of the plated Cu electrode not covered by the resist pattern were etched using an iron chloride aqueous solution to form a Cu electrode (plated and patterned Cu electrode) of size 5×5 mm.

The insulating resistance values when a voltage of 2 V was applied at room temperature to the thin film capacitors thus obtained were measured. Resistance values are shown converted into cm⁻² units. In order to maintain the original characteristics of the dielectric film to enable use as dielectric elements, it is desirable that high resistance be obtained for the insulating resistance values even after processes at the sputtered Cu electrodes and plated and patterned Cu electrodes. Specifically, for an insulating resistance value R1 at a sputtered Cu electrode, it is desirable that the insulating resistance value R2 at a plated and patterned Cu electrode be such that R2/R1>1/10.

Thin film capacitors employing a plated and patterned Cu electrode were subjected to observations using an optical microscope (1000×) and SEM (5000×), to inspect the state of damage to the dielectric film after etching with iron chloride solution. Ten regions each equivalent to 200×200 μm were observed, and the extent of damage was judged according to the following criteria, based on the total number (x) of cracks and film separations observed.
Damage present: x>0 (cracks exist)
No damage: x=0

TABLE 2

| | | Insulating | | |
|---|---|---|---|---|
| | | resistance value | | Damage to |
| | | Ω(/cm²) at RT, 2 V | | dielectric film |
| | | | plated, | after etching |
| Dielectric | Calcining | sputtered | patterned | with iron |
| composition | temperature | Cu | Cu | chloride |
| (Ba₁₋ₓSrₓ)_{y}TiO₃ | (° C.) | electrode | electrode | solution |
| x = 0.3, y = 1.03 | 320 | 1.2 × 10⁷ | 2.8 × 10⁶ | present |
| | 340 | 3.0 × 10⁷ | 5.2 × 10⁶ | present |
| | 360 | 5.3 × 10⁷ | 2.0 × 10⁶ | present |
| | 380 | 1.0 × 10⁸ | 3.2 × 10⁷ | present |
| | 400 | 2.3 × 10⁹ | 1.2 × 10⁹ | present |
| | 420 | 3.2 × 10⁹ | 2.3 × 10⁹ | present |
| | 440 | 7.8 × 10⁹ | 5.8 × 10⁹ | present |
| | 460 | 9.1 × 10⁹ | 8.8 × 10⁹ | present |
| | 480 | 8.3 × 10⁹ | 7.8 × 10⁹ | present |
| | 500 | Short | Short | present |
| | | | | (Ni oxidation) |
| x = 0.3, y = 1.00 | 320 | 9.8 × 10⁶ | 1.2 × 10⁶ | present |
| | 340 | 2.8 × 10⁷ | 2.3 × 10⁶ | present |
| | 360 | 4.8 × 10⁷ | 1.8 × 10⁶ | present |
| | 380 | 1.3 × 10⁸ | 1.2 × 10⁷ | present |
| | 400 | 9.3 × 10⁸ | 8.4 × 10⁸ | no |
| | 420 | 2.2 × 10⁹ | 1.3 × 10⁹ | no |
| | 440 | 5.5 × 10⁹ | 3.8 × 10⁹ | no |
| | 460 | 7.2 × 10⁹ | 6.3 × 10⁹ | no |
| | 480 | 6.2 × 10⁹ | 5.3 × 10⁹ | no |
| | 500 | Short | Short | present |
| | | | | (Ni oxidation) |
| x = 0.3, y = 0.97 | 320 | 8.8 × 10⁶ | 9.5 × 10⁵ | present |
| | 340 | 2.5 × 10⁷ | 2.1 × 10⁶ | present |
| | 360 | 2.8 × 10⁷ | 1.1 × 10⁶ | present |
| | 380 | 7.9 × 10⁷ | 9.0 × 10⁶ | present |
| | 400 | 5.3 × 10⁸ | 4.0 × 10⁸ | no |
| | 420 | 1.8 × 10⁹ | 1.1 × 10⁹ | no |
| | 440 | 5.2 × 10⁹ | 3.6 × 10⁹ | no |
| | 460 | 8.0 × 10⁹ | 5.2 × 10⁹ | no |
| | 480 | 5.5 × 10⁸ | 5.2 × 10⁸ | no |
| | 500 | Short | Short | present |
| | | | | (Ni oxidation) |
| x = 0.3, y = 0.90 | 320 | 5.7 × 10⁶ | 8.3 × 10⁵ | present |
| | 340 | 1.2 × 10⁷ | 1.1 × 10⁶ | present |
| | 360 | 2.2 × 10⁷ | 1.0 × 10⁶ | present |
| | 380 | 5.5 × 10⁷ | 8.2 × 10⁶ | present |
| | 400 | 2.3 × 10⁸ | 1.0 × 10⁸ | no |
| | 420 | 8.8 × 10⁸ | 8.2 × 10⁸ | no |
| | 440 | 1.3 × 10⁹ | 1.0 × 10⁹ | no |
| | 460 | 2.0 × 10⁹ | 1.3 × 10⁹ | no |
| | 480 | 3.2 × 10⁸ | 2.4 × 10⁸ | no |
| | 500 | Short | Short | present |
| | | | | (Ni oxidation) |
| x = 0.3, y = 0.85 | 320 | 7.4 × 10⁵ | 7.2 × 10⁴ | present |
| | 340 | 6.8 × 10⁶ | 8.7 × 10⁵ | present |
| | 360 | 8.7 × 10⁶ | 7.7 × 10⁵ | present |
| | 380 | 4.5 × 10⁷ | 4.3 × 10⁶ | present |
| | 400 | 8.4 × 10⁷ | 8.0 × 10⁷ | no |
| | 420 | 2.0 × 10⁸ | 1.5 × 10⁸ | no |
| | 440 | 7.8 × 10⁸ | 7.0 × 10⁸ | no |
| | 460 | 8.2 × 10⁸ | 7.9 × 10⁸ | no |
| | 480 | 1.2 × 10⁸ | 1.0 × 10⁸ | no |
| | 500 | Short | Short | present |
| | | | | (Ni oxidation) |
| x = 0.3, y = 0.80 | 320 | 8.0 × 10⁴ | 6.4 × 10³ | present |
| | 340 | 2.8 × 10⁵ | 4.5 × 10⁴ | present |
| | 360 | 3.5 × 10⁵ | 5.6 × 10⁴ | present |
| | 380 | 5.6 × 10⁵ | 4.3 × 10⁵ | present |
| | 400 | 6.0 × 10⁵ | 5.4 × 10⁵ | no |
| | 420 | 7.3 × 10⁵ | 6.2 × 10⁵ | no |
| | 440 | 8.2 × 10⁵ | 7.1 × 10⁵ | no |
| | 460 | 1.2 × 10⁶ | 8.7 × 10⁵ | no |
| | 480 | 8.9 × 10⁵ | 7.8 × 10⁵ | no |
| | 500 | Short | Short | present |
| | | | | (Ni oxidation) |

The composition and calcining temperature of dielectric films are shown in Table 2, together with evaluation results for each case. When y(=A/B)>1.00, if the calcining temperature was 400° C. or higher, the resistance value after plating and patterning to form the Cu electrode was maintained at a satisfactory level, but after etching, damage to the dielectric film was observed.

On the other hand, when y≦1.00, by setting the calcining temperature to 400° C. or higher, the fluctuation in resistance even after formation of the plated and patterned Cu electrode is R2/R1>1/10, so that a comparatively satisfactory resistance value is maintained, and at the same time no damage was observed in the dielectric film after etching with iron chloride solution. When damage to the dielectric film existed after etching, in subsequent processes leading to completion of a product such damage is a factor rendering processes unstable, and there is the possibility of problems arising when there is a need to remove insulation at the dielectric. Hence it is necessary to avoid circumstances in which the dielectric may be damaged in etching. It is seen that when y<0.85, the film insulating resistance value is 10⁶Ω or lower. That is, it was confirmed that if the MOD solution (or dielectric film) has a composition with 0.85≦y≦1.00 (and preferably 0.85≦y<1.00), and moreover the calcining temperature is 400° C. or higher, the dielectric film has sufficient tolerance of wet processes such as Cu plating and etching with iron chloride solution, and has a high insulating resistance value.

When the calcining temperature exceeded 480° C., the Ni foil was oxidized, and damage due to oxidation was confirmed. Thus it was confirmed that a calcining temperature of 480° C. or lower is preferable.

### Example 2

Except for changing the etchant, etching the plated Cu electrode with a copper chloride aqueous solution, and employing as parameter (x,y) sets for the compositions of the dielectric films (0.3,1.03), (0.3,1.00), (0.3,0.995) and (0.3,0.99), conditions similar to those of Example 1 were employed to fabricate thin film capacitors.

The dielectric film composition, insulating resistance after electrode formation, and damage to the dielectric film after patterning the plated Cu electrode with copper chloride solution for elements fabricated in experiments were measured and compared using methods similar to those of Example 1, and results appear in Table 3.

TABLE 3

| | | Insulating | | |
|---|---|---|---|---|
| | | resistance value | | Damage to |
| | | Ω(/cm²) at RT, 2 V | | dielectric film |
| | | | plated, | after etching |
| Dielectric | Calcining | sputtered | patterned | with copper |
| composition | temperature | Cu | Cu | chloride |
| (Ba₁₋ₓSrₓ)_{y}TiO₃ | (° C.) | electrode | electrode | solution |
| x = 0.3, y = 1.03 | 360 | 4.8 × 10⁷ | 1.1 × 10⁶ | present |
| | 380 | 9.2 × 10⁷ | 8.8 × 10⁶ | present |
| | 400 | 2.0 × 10⁹ | 1.0 × 10⁹ | present |
| | 420 | 2.8 × 10⁹ | 1.9 × 10⁹ | present |
| | 440 | 7.0 × 10⁹ | 6.2 × 10⁹ | present |
| | 480 | 8.1 × 10⁹ | 7.2 × 10⁹ | present |
| | 500 | Short | Short | present |
| | | | | (Ni oxidation) |
| x = 0.3, y = 1.00 | 360 | 5.0 × 10⁷ | 1.0 × 10⁶ | present |
| | 380 | 1.5 × 10⁸ | 8.7 × 10⁶ | present |
| | 400 | 9.0 × 10⁸ | 1.2 × 10⁸ | present |
| | 420 | 3.2 × 10⁹ | 9.8 × 10⁸ | present |
| | 440 | 6.0 × 10⁹ | 1.0 × 10⁹ | present |
| | 480 | 5.8 × 10⁹ | 2.9 × 10⁹ | present |
| | 500 | Short | Short | present |
| | | | | (Ni oxidation) |
| x = 0.3, | 360 | 4.0 × 10⁷ | 3.0 × 10⁶ | present |
| y = 0.995 | 380 | 9.1 × 10⁷ | 8.6 × 10⁶ | present |
| | 400 | 8.5 × 10⁸ | 6.1 × 10⁸ | no |
| | 420 | 3.1 × 10⁹ | 1.2 × 10⁹ | no |
| | 440 | 5.3 × 10⁹ | 4.7 × 10⁹ | no |
| | 480 | 6.8 × 10⁸ | 6.0 × 10⁸ | no |
| | 500 | Short | Short | present |
| | | | | (Ni oxidation) |
| x = 0.3, y = 0.99 | 360 | 3.0 × 10⁷ | 2.0 × 10⁶ | present |
| | 380 | 8.2 × 10⁷ | 8.5 × 10⁶ | present |
| | 400 | 5.5 × 10⁸ | 4.1 × 10⁸ | no |
| | 420 | 2.2 × 10⁹ | 1.3 × 10⁹ | no |
| | 440 | 4.8 × 10⁹ | 3.7 × 10⁹ | no |
| | 480 | 6.0 × 10⁸ | 5.7 × 10⁸ | no |
| | 500 | Short | Short | present |
| | | | | (Ni oxidation) |

When using copper chloride solution as the etchant, in contrast with iron chloride solution, even at y(=A/B)=1.00 the frequency of occurrence was far less than at y(=A/B)=1.03, but damage was observed.

Hence upon considering the change in etchant and modification of the etching conditions (change in temperature and similar), it can be said that a value y(=A/B)<1.00 is preferable for suppressing damage due to the etchant.

### Example 3

Except for using an NiPd alloy and Pt in addition to the Ni foil of Example 1 as a metal layer, setting the dielectric film composition to only x=0.3 and y=1 as in the case of #2 in Table 1, and setting the calcining temperature to only 400° C., conditions similar to those of Example 1 were used to fabricate thin film capacitors. As the NiPd metal layer, an NiPd alloy foil, was used, and as the Pt layer a Pt foil was used to form the dielectric film.

Insulating resistance values of dielectric films fabricated in experiments after electrode formation were measured by a method similar to that of Example 1 and compared, and the results appear in Table 4.

TABLE 4

| | | Insulating resistance value | | | | | |
|---|---|---|---|---|---|---|---|
| Dielectric | Calcining | Ω(/cm²) at RT, 2 V | | | | | |
| composition | temperature | sputtered Cu electrode | | | plated, patterned Cu electrode | | |
| (Ba₁₋ₓSrₓ)_{y}TiO₃ | (° C.) | Pt | Ni | NiPd alloy | Pt | Ni | NiPd alloy |
| x = 0.3, | 400 | 6.3 × 10⁵ | 9.3 × 10⁸ | 8.0 × 10⁸ | 5.1 × 10⁵ | 8.4 × 10⁸ | 7.2 × 10⁸ |
| y = 1.00 | | | | | | | |

The resistance value of dielectric films fabricated on Pt foil was reduced compared with dielectric films on Ni foil and on NiPd alloy foil.

In the case of NiPd alloys, dielectric films were inspected for damage after etching with iron chloride solution using a method similar to that of Example 1, but no damage was observed.

Because the metal foil itself can be a wiring electrode when dielectric film is formed on metal foil, ease of patterning may be sought. In the case of one type of rare metal such as Pt, when forming wires using wet etching, etching is extremely difficult using the iron chloride solution and copper chloride solution generally employed. For this reason, wet etching using for example a hydrofluoric acid solution, or milling processing instead of wet etching, must be employed. These processes generally cannot be performed as easily as wet etching using iron chloride or copper chloride. On the other hand, in the case of Ni or an Ni alloy, wet etching using iron chloride solution or similar can be used, so that wire formation and other processing is easy.

Hence in addition to electrical characteristics, when considering electrode patterning and other subsequent processes, Ni and alloys comprising Ni are optimal for use as metal layers or metal foil in thin films due to the comparative ease of wet etching.

What is claimed is:

1. A method for manufacturing a dielectric element, comprising the steps of:
forming a film of a solution comprising a precursor on a metal layer comprising Ni or an alloy comprising Ni;
heating the solution film on the metal layer in an oxidizing atmosphere, to form a calcined film comprising a dielectric material generated from the precursor; and
annealing the calcined film to form a dielectric film comprising the dielectric material that has been crystallized,
wherein the dielectric material is a metal oxide which forms a perovskite-structure crystal having A sites and B sites,
the solution of the precursor comprises an element occupying the A sites and an element occupying the B sites in the dielectric film, at a molar ratio of the element occupying A sites to the element occupying B sites of 0.85 or higher and 1.00 or lower, and
the temperature of heating of the solution film is 400 to 480° C.

2. The method for manufacturing a dielectric element according to claim 1, wherein the element occupying A sites is at least one element selected from the group consisting of Ba, Sr, Ca, and Pb, and the element occupying B sites is at least one element selected from the group consisting of Ti, Zr, Hf, and Sn.

3. The method for manufacturing a dielectric element according to claim 1, wherein the calcined film is annealed at 400° C. to 1200° C. in a reduced-pressure atmosphere at 0.001 to 10 Pa.
